(19) United States
(12) Patent Application Publication
(10) Pub. No.: US 2025/0357110 A1
(43) Pub. Date: Nov. 20, 2025

(54) SUBSTRATE PROCESSING METHOD AND SUBSTRATE PROCESSING APPARATUS

(71) Applicant: Tokyo Electron Limited, Tokyo (JP)

(72) Inventors: Daichi ITO, Yamanashi (JP); Jun OGAWA, Yamanashi (JP)

(21) Appl. No.: 19/175,518

(22) Filed: Apr. 10, 2025

(30) Foreign Application Priority Data
May 15, 2024 (JP) 2024-079239

(51) Int. Cl. H01L 21/02; C23C 16/52; C23C 16/56

(52) U.S. Cl. CPC H01L 21/02326; C23C 16/52; C23C 16/56; H01L 21/02126; H01L 21/0234

(57) ABSTRACT

A technique capable of controlling the etching amount of a nitride film is provided. A substrate processing method includes: (a) preparing a substrate having a nitride film on a surface thereof; (b) exposing the substrate to a plasma generated from a first processing gas containing hydrogen gas and oxygen gas; (c) supplying a second processing gas containing a fluorine-containing gas and a basic gas to the substrate; (d) performing the (b) and the (c) in this order a first number of times; and (e) thermally treating the substrate after the (d).

### CROSS-REFERENCE TO RELATED APPLICATION

The present application claims priority under 35 U.S.C. § 119 to Japanese Patent Application No. 2024-079239, filed May 15, 2024, the contents of which are incorporated herein by reference in their entireties.

### BACKGROUND OF THE INVENTION

### Field of the Invention

The present disclosure relates to a substrate processing method and a substrate processing apparatus.

### Description of the Related Art

A disclosed technique supplies hydrogen gas and oxygen gas to a SiCN film formed on a surface of a substrate to oxidize a surface layer of the SiCN film and form an oxide film, and subsequently removes the oxide film by etching (see, for example, Japanese Patent Application Laid-Open Publication No. 2023-179001).

### SUMMARY OF THE INVENTION

A substrate processing method according to one embodiment of the present disclosure includes: (a) preparing a substrate having a nitride film on a surface thereof; (b) exposing the substrate to a plasma generated from a first processing gas containing hydrogen gas and oxygen gas; (c) supplying a second processing gas containing a fluorine-containing gas and a basic gas to the substrate; (d) performing the (b) and the (c) in this order a first number of times; and (e) thermally treating the substrate after the (d).

### BRIEF DESCRIPTION OF THE DRAWINGS

FIG. 1 is a flowchart showing a substrate processing method according to an embodiment;

FIG. 2 is a vertical cross-sectional view showing a substrate processing apparatus according to an embodiment;

FIG. 3 is a horizontal cross-sectional view showing a substrate processing apparatus according to an embodiment;

FIG. 4 is a graph showing the relationship between a first number of times and an etching amount of an SiCN film;

FIG. 5 is a graph showing the result of a surface analysis of an SiO₂ film that is not subjected to a radical treatment;

FIG. 6 is a graph showing the result of a surface analysis of an SiCN film that is not subjected to a radical treatment;

FIG. 7 is a graph showing the result of a surface analysis of an SiCN film subjected to a radical treatment;

FIG. 8 is a graph showing an oxygen concentration in a surface layer of an SiCN film; and

FIG. 9 is a graph showing an etching amount of an SiCN film.

### DETAILED DESCRIPTION OF THE DISCLOSURE

Hereinafter, non-limiting exemplary embodiments of the present disclosure will be described with reference to the attached drawings. In all of the attached drawings, the same or corresponding members or parts will be denoted by the same or corresponding reference numerals, and duplicate descriptions will be omitted.

### [Substrate Processing Method]

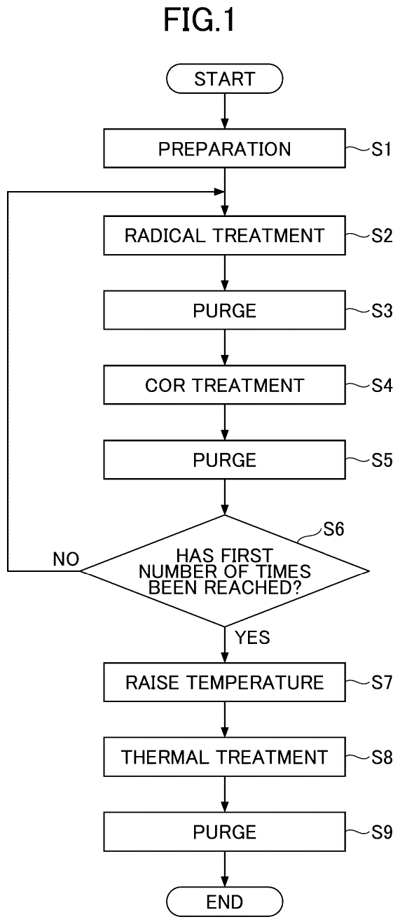

A substrate processing method according to an embodiment will be described with reference to FIG. 1. FIG. 1 is a flowchart showing a substrate processing method according to an embodiment. The substrate processing method according to the embodiment includes steps S1 to S9 shown in FIG. 1.

In step S1, a substrate having a nitride film on a surface thereof is prepared. The substrate is, for example, a silicon wafer. The nitride film is, for example, a film containing silicon (Si) and nitrogen (N). The film containing silicon and nitrogen is, for example, an SiN film or an SiCN film. The nitride film may further contain an element different from silicon and nitrogen. The different element is, for example, oxygen (O), boron (B), or a combination thereof. The nitride film may be a film containing boron and nitrogen. The film containing boron and nitrogen is, for example, a BN film.

In step S2, the substrate prepared in step S1 is subjected to a radical treatment. The radical treatment includes exposing the substrate to a plasma generated from a first processing gas containing hydrogen gas and oxygen gas. The plasma contains active species, such as oxygen radicals and the like. In the radical treatment, the active species acts on the surface layer of the nitride film, thereby oxidizing the surface layer of the nitride film and forming an oxide layer. In step S2, it is possible to adjust the thickness of the oxide layer to be formed on the surface layer of the nitride film, by changing the concentration of the oxygen gas contained in the first processing gas. The first processing gas may further contain an inert gas, such as argon gas, nitrogen gas, and the like. Step S2 may include maintaining the temperature of the substrate at a first temperature. The first temperature is, for example, 80° C. or lower.

In step S3, purging is performed. The purging may include vacuuming the processing space in which the substrate is processed, thereby exhausting any gas remaining in the processing space. The purging may include exhausting any gas remaining in the processing space by supplying an inert gas, such as argon gas, nitrogen gas, or the like, into the processing space in which the substrate is processed.

In step S4, a Chemical Oxide Removal (COR) treatment is performed. The COR treatment includes supplying a second processing gas containing a fluorine-containing gas and a basic gas to the substrate without generating a plasma. In the COR process, the fluorine-containing gas and the basic gas react with the oxide layer to denature the oxide layer and produce ammonium silicofluoride [(NH₄)₂SiF₆], which is a reaction product. The fluorine-containing gas is, for example, hydrogen fluoride (HF) gas. The basic gas is, for example, ammonia (NH₃) gas. The second processing gas may further contain an inert gas, such as argon gas, nitrogen gas, and the like. Step S4 may include maintaining the temperature of the substrate at a second temperature. The second temperature is, for example, 50° C. or higher and 100° C. or lower. The second temperature may be the same as the first temperature. In this case, it is possible to continuously perform the radical treatment and the COR treatment without changing the temperature. Therefore, productivity is improved.

In step S5, purging is performed. The purging in step S5 may be the same as the purging in step S3.

In step S6, it is determined whether or not steps S2 to S5 have been performed in this order a first number of times. When the number of times these steps have been performed has not reached the first number of times (NO in step S6), steps S2 to S5 are performed again. When the number of times these steps have been performed has reached the first number of times (YES in step S6), the flow proceeds to step S7. Thus, the thickness of the oxide layer formed on the surface layer of the nitride film is adjusted by repeating steps S2 to S5 in this order until the number of times these steps have been performed has reached the first number of times. The first number of times may be 1, 2, or greater.

In step S7, the temperature of the substrate is raised from the second temperature to the third temperature. The third temperature is higher than the second temperature. The third temperature is, for example, 200° C. or higher.

In step S8, the substrate is thermally treated. The thermal treatment includes thermally treating the substrate in an atmosphere formed of an inert gas, such as argon gas, nitrogen gas, and the like, while maintaining the temperature of the substrate at the third temperature. In the thermal treatment, ammonium silicofluoride, which is the reaction product, is sublimated and removed from the substrate.

In step S9, purging is performed. The purging in step S9 may be the same as the purging in step S3. After the purging is performed in step S9, the flow is ended.

As described above, according to the substrate processing method of the embodiment, a substrate having a nitride film on a surface thereof is prepared, subjected to the radical treatment and the COR treatment in this order the first number of times, and then subjected to the thermal treatment. In this case, by changing the first number of times, it is possible to adjust the thickness of the oxide layer formed on the surface layer of the nitride film. Therefore, the etching amount of the nitride film can be controlled.

In the embodiment, steps S2 to S9 may be performed in the same processing chamber. In this case, the nitride film can be etched and removed in one processing chamber. However, a part of steps S2 to S9 may be performed in a different processing chamber. For example, steps S8 and S9 may be performed in a different processing chamber from that in which steps S2 to S6 are performed. In this case, step S7 can be omitted.

The substrate processing method according to the embodiment may be performed in a processing chamber configured to contain a plurality of substrates in a shelf form. In this case, nitride films can be etched from a plurality of substrates at a time. Therefore, productivity is improved.

### [Substrate Processing Apparatus]

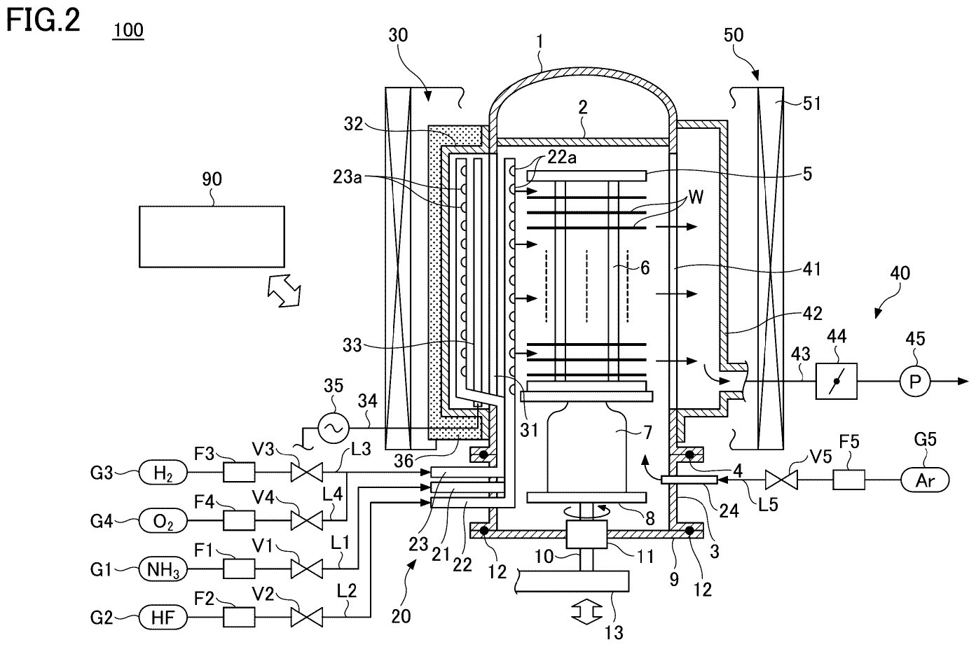

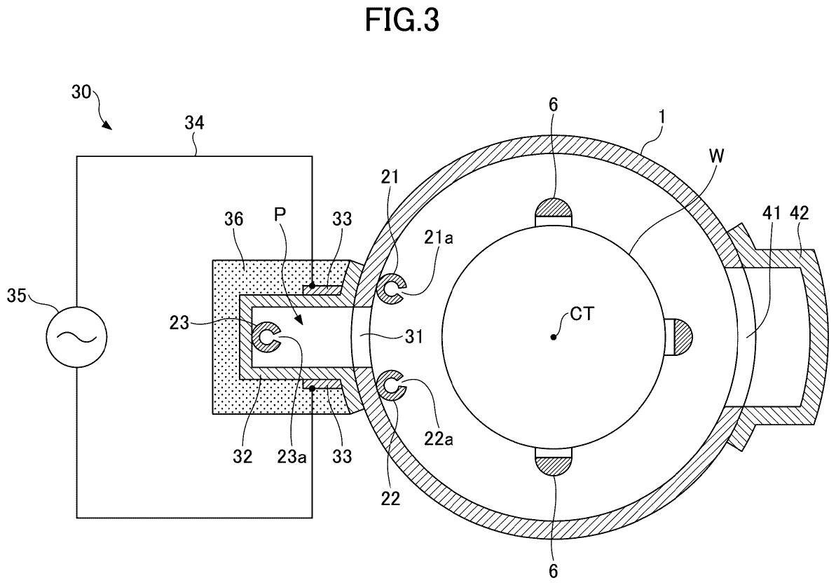

A substrate processing apparatus 100 according to an embodiment will be described with reference to FIGS. 2 and 3. FIG. 2 is a vertical cross-sectional view showing the substrate processing apparatus 100 according to the embodiment. FIG. 3 is a horizontal cross-sectional view showing the substrate processing apparatus 100 according to the embodiment. As shown in FIGS. 2 and 3, the substrate processing apparatus 100 includes a processing chamber 1, a gas supply part 20, a plasma generation part 30, a gas exhaust part 40, a heating part 50, and a controller 90.

The processing chamber 1 has a ceiled longitudinal cylindrical shape opened at the lower end. The processing chamber 1 is formed of, for example, quartz. A ceiling plate 2 is provided in the processing chamber 1 near the upper end of the processing chamber 1, and a region under the ceiling plate 2 is sealed. The ceiling plate 2 is formed of, for example, quartz. A cylindrical metallic manifold 3 is connected to the opening at the lower end of the processing chamber 1 via a seal member 4. The seal member 4 is, for example, an O-ring.

The manifold 3 supports the lower end of the processing chamber 1. A boat 5 is inserted into the processing chamber 1 from under the manifold 3. The boat 5 holds a plurality of (for example, 25 to 150) substrates W substantially horizontally at intervals provided along the vertical direction. The boat 5 is formed of, for example, quartz. The boat 5 has, for example, three supports 6, and the plurality of substrates W are supported in grooves formed in the supports 6.

The boat 5 is placed on a rotating table 8 via a thermal insulating cylinder 7. The thermal insulating cylinder 7 is formed of, for example, quartz. The thermal insulating cylinder 7 restricts heat dissipation from the opening at the lower end of the manifold 3. The rotating table 8 is supported on a rotation shaft 10. The opening at the lower end of the manifold 3 is opened and closed by a cover 9. The cover 9 is formed of, for example, a metal material, such as stainless steel, and the like. The rotation shaft 10 penetrates the cover 9.

A magnetic fluid seal 11 is provided at the part penetrated by the rotation shaft 10. The magnetic fluid seal 11 airtightly seals and rotatably supports the rotation shaft 10. A seal member 12 is provided between the periphery of the cover 9 and the lower end of the manifold 3 for maintaining airtightness in the processing chamber 1. The seal member 12 is, for example, an O-ring.

The rotation shaft 10 is attached to an end of an arm 13 supported by a lifting mechanism, such as a boat elevator and the like. When the arm 13 is moved upward or downward, the boat 5, the thermal insulating cylinder 7, the rotating table 8, and the cover 9 are moved upward or downward integrally with the rotation shaft 10, to be inserted into or removed from the processing chamber 1.

The gas supply part 20 supplies various processing gases into the processing chamber 1. The gas supply part 20 includes, for example, a gas nozzle 21, a gas nozzle 22, a gas nozzle 23, and a gas nozzle 24. The gas nozzle 21, the gas nozzle 22, the gas nozzle 23, and the gas nozzle 24 are formed of, for example, quartz. The gas supply part 20 may further include another gas nozzle.

The gas nozzle 21 has an L-letter shape that penetrates the side wall of the manifold 3 inward, and is bent upward and extends vertically. A vertical part of the gas nozzle 21 is provided in the processing chamber 1. A plurality of gas holes 21a are provided in the vertical part of the gas nozzle 21. The plurality of gas holes 21a are provided at predetermined intervals along the extending direction of the gas nozzle 21. Each gas hole 21a is oriented to, for example, the center CT of the processing chamber 1.

A supply path L1 is connected to the gas nozzle 21. The supply path L1 is provided with a supply source G1 of ammonia gas, a mass flow controller F1, and an opening/closing valve V1 in order from the upstream side to the downstream side in the gas flow direction. The ammonia gas is an example of the basic gas. The supply timing of the ammonia gas in the supply source G1 is controlled by the opening/closing valve V1, and the flow rate thereof is adjusted to a predetermined flow rate by the mass flow controller F1. The ammonia gas flows into the gas nozzle 21 through the supply path L1 and is discharged horizontally from the plurality of gas holes 21a toward the center CT of the processing chamber 1.

The gas nozzle 22 has an L-letter shape that penetrates the side wall of the manifold 3 inward, and is bent upward and extends vertically. A vertical part of the gas nozzle 22 is provided in the processing chamber 1. A plurality of gas holes 22a are provided in the vertical part of the gas nozzle 22. The plurality of gas holes 22a are provided at predetermined intervals along the extending direction of the gas nozzle 22. Each gas hole 22a is oriented to, for example, the center CT of the processing chamber 1.

A supply path L2 is connected to the gas nozzle 22. The supply path L2 is provided with a supply source G2 of hydrogen fluoride gas, a mass flow controller F2, and an opening/closing valve V2 in order from the upstream side to the downstream side in the gas flow direction. The hydrogen fluoride gas is an example of the fluorine-containing gas. The supply timing of the hydrogen fluoride gas in the supply source G2 is controlled by the opening/closing valve V2, and the flow rate thereof is adjusted to a predetermined flow rate by the mass flow controller F2. The hydrogen fluoride gas flows into the gas nozzle 22 through the supply path L2, and is discharged horizontally from the plurality of gas holes 22a toward the center CT of the processing chamber 1.

The gas nozzle 23 has an L-letter that penetrates the side wall of the manifold 3 inward, and is bent upward and extends vertically. A vertical part of the gas nozzle 23 is provided in a plasma generation space P. A plurality of gas holes 23a are provided in the vertical part of the gas nozzle 23. The plurality of gas holes 23a are provided at predetermined intervals along the extending direction of the gas nozzle 23. Each gas hole 23a is oriented to, for example, the center CT of the processing chamber 1.

A supply path L3 is connected to the gas nozzle 23. The supply path L3 is provided with a supply source G3 of hydrogen gas, a mass flow controller F3, and an opening/closing valve V3 in order from the upstream side to the downstream side in the gas flow direction. The supply timing of the hydrogen gas in the supply source G3 is controlled by the opening/closing valve V3, and the flow rate thereof is adjusted to a predetermined flow rate by the mass flow controller F3. The hydrogen gas flows into the gas nozzle 23 through the supply path L3, and is discharged horizontally from the plurality of gas holes 23a toward the center CT of the processing chamber 1.

A supply path L4 is connected to the gas nozzle 23. The supply path L4 may be connected to the supply path L3 at the downstream of the opening/closing valve V3. The supply path L4 is provided with a supply source G4 of oxygen gas, a mass flow controller F4, and an opening/closing valve V4 in order from the upstream side to the downstream side in the gas flow direction. The supply timing of the oxygen gas in the supply source G4 is controlled by the opening/closing valve V4, and the flow rate thereof is adjusted to a predetermined value by the mass flow controller F4. The oxygen gas flows into the gas nozzle 23 through the supply path L4, and is discharged horizontally from the plurality of gas holes 23a toward the center CT of the processing chamber 1.

The gas nozzle 24 has a straight tube shape that penetrates the side wall of the manifold 3 and extends horizontally. An end part of the gas nozzle 24 is provided in the processing chamber 1. The end part of the gas nozzle 24 is opened.

A supply path L5 is connected to the gas nozzle 24. The supply path L5 is provided with a supply source G5 of argon gas, a mass flow controller F5, and an opening/closing valve V5 in order from the upstream side to the downstream side in the gas flow direction. The argon gas is an example of the inert gas. The supply timing of the argon gas in the supply source G5 is controlled by the opening/closing valve V5, and the flow rate thereof is adjusted to a predetermined flow rate by the mass flow controller F5. The argon gas flows into the gas nozzle 24 through the supply path L5 and is discharged into the processing chamber 1 through the opening at the end part.

The plasma generation part 30 is provided on a part of the side wall of the processing chamber 1. The plasma generation part 30 generates a plasma from the hydrogen gas and the oxygen gas supplied from the gas nozzle 23. The plasma generation part 30 includes a plasma partition wall 32, a pair of plasma electrodes 33, a power supply line 34, an RF power source 35, and an insulating protection cover 36.

The plasma partition wall 32 is airtightly welded to the outer wall of the processing chamber 1. The plasma partition wall 32 is formed of, for example, quartz. The plasma partition wall 32 has a box cross-sectional shape and covers an opening 31 formed in the side wall of the processing chamber 1. The opening 31 is formed in an elongated shape extending in the vertical direction so as to be able to cover all the substrates W supported by the boat 5 in the vertical direction. The plasma partition wall 32 defines the plasma generation space P, which is an inner space communicating with the interior of the processing chamber 1.

The pair of plasma electrodes 33, each of which has an elongated shape, are situated on the outer surfaces of walls of the plasma partition wall 32 on facing sides, such that the pair of plasma electrodes 33 extend along the vertical direction and face each other. The power supply line 34 is connected to the lower end of each plasma electrode 33.

The power supply line 34 electrically connects each plasma electrode 33 and the RF power source 35. For example, one end of the power supply line 34 is connected to the lower end of each plasma electrode 33 on the side of a shorter side of the plasma electrode 33, and the other end of the power supply line 34 is connected to the RF power source 35.

The RF power source 35 is electrically connected to the lower end of each plasma electrode 33 through the power supply line 34. The RF power source 35 supplies an RF power of, for example, 13.56 MHz to the pair of plasma electrodes 33. Thus, an RF power is applied to the plasma generation space P defined by the plasma partition wall 32.

The insulating protection cover 36 is mounted on the outer side of the plasma partition wall 32 so as to cover the plasma partition wall 32. A refrigerant path (not shown) is provided inside the insulating protection cover 36. The plasma electrodes 33 are cooled by flowing a cooled refrigerant, such as nitrogen gas or the like, through the refrigerant path. A shield (not shown) may be provided between the plasma electrodes 33 and the insulating protection cover 36 so as to cover the plasma electrodes 33. The shield is formed of, for example, a good conductor, such as a metal or the like, and is electrically grounded.

The gas exhaust part 40 has a gas exhaust port 41. The gas exhaust port 41 is provided in a side wall part of the processing chamber 1. The gas exhaust port 41 is provided at a position facing the opening 31. The gas exhaust port 41 is formed in an elongated shape extending vertically so as to match the boat 5. A cover member 42 formed in a U-letter cross-sectional shape so as to cover the gas exhaust port 41 is attached to a part of the processing chamber 1 corresponding to the gas exhaust port 41. The cover member 42 extends upward along the side wall of the processing chamber 1. A gas exhaust pipe 43 is connected to a lower part of the cover member 42. The gas exhaust pipe 43 is provided with a pressure regulating valve 44 and a vacuum pump 45 in order from the upstream side to the downstream side in the gas flow direction. The pressure regulating valve 44 regulates the pressure in the processing chamber 1. The vacuum pump 45 exhausts gases from the processing chamber 1.

The heating part 50 includes a heater 51. The heater 51 has a cylindrical shape surrounding the processing chamber 1 on the outer side of the processing chamber 1 in the radial direction. The heater 51 heats each substrate W contained in the processing chamber 1 by heating the entire lateral circumference of the processing chamber 1.

The controller 90 is an electronic circuit, such as a Central Processing Unit (CPU), a Field Programmable Gate Array (FPGA), an Application Specific Integrated Circuit (ASIC), and the like. The controller 90 performs various control operations described in this specification by executing instruction codes stored in a memory or by being designed as a circuit for a special application.

### [Operation of Substrate Processing Apparatus]

The operation of the substrate processing apparatus 100 when the substrate processing method according to the embodiment is performed in the substrate processing apparatus 100 will be described below.

First, the controller 90 raises the arm 13 to load the boat 5 holding a plurality of substrates W into the processing chamber 1, and airtightly closes and seals the opening at the lower end of the processing chamber 1 with the cover 9. Each substrate W has a nitride film on a surface thereof.

Next, the controller 90 controls each part of the substrate processing apparatus 100 so as to perform steps S2 to S9 of the substrate processing method described above. Thus, at least a part of the nitride film formed on the surface of each substrate W is etched and removed. The controller 90 adjusts the thickness of the oxide layer to be formed on the surface layer of the nitride film by changing the first number of times in step S6. Thus, the etching amount of the nitride film can be controlled.

Next, the controller 90 raises the pressure in the processing chamber 1 to the open-air pressure, lowers the temperature in the processing chamber 1 to an unloading temperature, and then lowers the arm 13 to unload the boat 5 from the processing chamber 1. Thus, the processing of the plurality of substrates W is completed.

### [Experiments]

### (First Experiment)

First, a substrate having an SiCN film on a surface thereof was prepared. Next, the prepared substrate was contained in the processing chamber 1 of the substrate processing apparatus 100, and steps S2 to S9 of the substrate processing method described above were performed in the processing chamber 1. In step S6, the first number of times was changed. The first number of times was 3, 5, and 10. For comparison, steps S3 to S9 were performed without the radical treatment in step S2. The conditions of the radical treatment (step S2), the COR treatment (step S4), and the thermal treatment (step S8) were as follows.

### (Radical Treatment)

Substrate temperature: 65° C.
Time: 10 minutes
RF power: ON
First processing gas: hydrogen gas+oxygen gas

### (COR Treatment)

Substrate temperature: 65° C.
Time: 1 minute
RF power: OFF
Second processing gas: hydrogen fluoride gas/ammonia gas=300 sccm/300 sccm (Thermal Treatment)
Substrate temperature: 300° C.
Treatment atmosphere: nitrogen gas

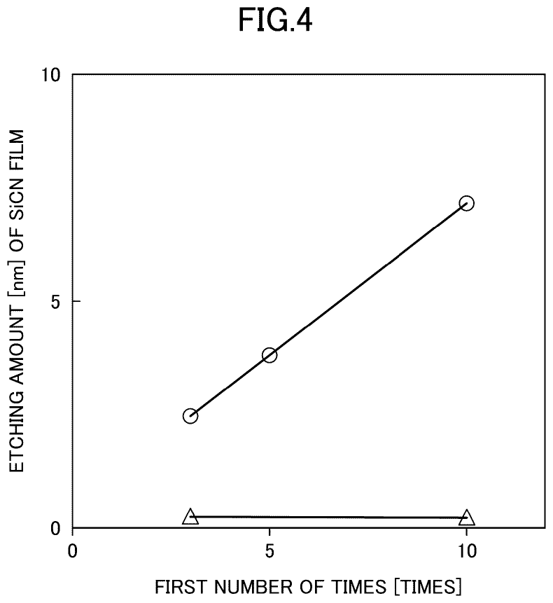

Next, the etching amount of the SiCN film was measured. FIG. 4 shows the relationship between the first number of times and the etching amount of the SiCN film. In FIG. 4, the horizontal axis indicates the first number of times [times], and the vertical axis indicates the etching amount [nm] of the SiCN film. In FIG. 4, the circles indicates the results in the cases where the radical treatment was performed, and the triangles indicate the results in the cases where the radical treatment was not performed.

As shown in FIG. 4, the SiCN film was almost not etched when the radical treatment was not performed, while the SiCN film was etched when the radical treatment was performed. This result showed that it was possible to etch the SiCN film by performing the radical treatment before the COR treatment.

As shown in FIG. 4, in the cases where the radical treatment was performed, the etching amount of the SiCN film increased as the first number of times increased. This result showed that it was possible to control the etching amount of the SiCN film by changing the first number of times. Specifically, it was possible to increase the etching amount of the SiCN film by increasing the first number of times.

### (Second Experiment)

First, a substrate having, on a surface thereof, a SiO₂ film that was not subjected to the radical treatment, a substrate having, on a surface thereof, a SiCN film that was not subjected to the radical treatment, and a substrate having, on a surface thereof, a SiCN film that was subjected to the radical treatment were prepared. The substrate having, on a surface thereof, the SiCN film that was subjected to the radical treatment was formed by accommodating a substrate having, on a surface thereof, a SiCN film that was not subjected to the radical treatment into the processing chamber 1 of the substrate processing apparatus 100, and subjecting the substrate to the radical treatment in step S2 of the substrate processing method described above in the processing chamber 1. The conditions of the radical treatment were the same as those of the radical treatment in the first experiment.

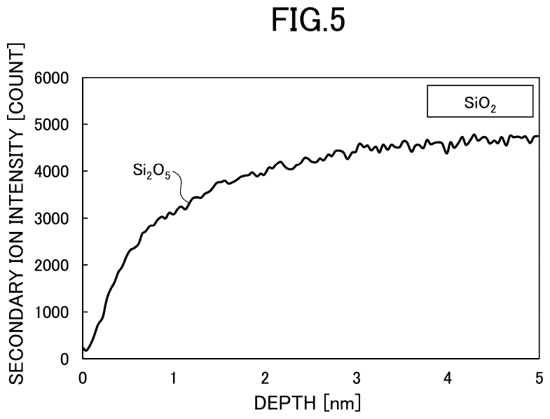

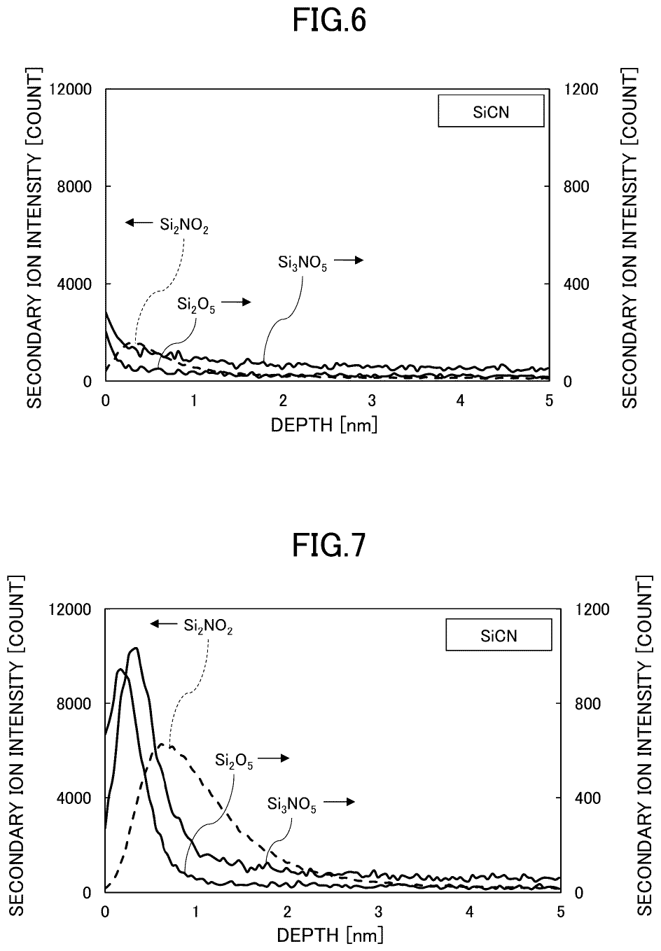

Next, a surface analysis of the films on the surfaces of the prepared substrates was performed by Time-of-Flight Secondary Ion Mass Spectrometry (TOF-SIMS). FIG. 5 shows the result of the surface analysis of the SiO₂ film that was not subjected to the radical treatment. FIG. 6 shows the result of the surface analysis of the SiCN film that was not subjected to the radical treatment. FIG. 7 shows the result of the surface analysis of the SiCN film that was subjected to the radical treatment. In FIGS. 5 to 7, the horizontal axis indicates the SiO₂-quivalent depth [nm] from the film surface, and the vertical axis indicates the secondary ion intensity [count].

As shown in FIG. 5, secondary ion intensities attributable to an Si₂O₅ component were detected from the SiO₂ film that was not subjected to the radical treatment.

As shown in FIGS. 6 and 7, secondary ion intensities attributable to an Si₂O₅ component, an Si₂NO₂ component, and an Si₃NO₅ component were higher in the SiCN film that was subjected to the radical treatment than in the SiCN film that was not subjected to the radical treatment. In particular, the secondary ion intensities derived from the Si₂O₅ component, the Si₂NO₂ component, and the Si₃NO₅ components increased remarkably in the range of 0 nm to 2 nm from the surface of the SiCN film. From this result, it is considered that the surface layer of the SiCN film was oxidized by the radical treatment on the SiCN film, to form an oxide layer. Especially, since the Si₂O₅ component is a component contained in an SiO₂ film, it is considered that the surface layer of the SiCN film had become close to an SiO₂ film through the radical treatment on the SiCN film.

### (Third Experiment)

Next, substrates having SiCN films on surfaces thereof were prepared. Next, the prepared substrates were accommodated in the processing chamber 1 of the substrate processing apparatus 100, and subjected to the radical treatment of Step S2 of the substrate processing method in the processing chamber 1. In Step S2, the radical treatment time, the RF power, and the concentration of the oxygen gas contained in the first processing gas were changed. The conditions of the radical treatment were as follows.

### (Radical Treatment)

Substrate temperature: 65° C.
Time: 0 minutes, 10 minutes, 30 minutes
RF power: OFF, ON
Concentration of the oxygen gas contained in the first processing gas: 75.8%, 20.4%

Next, the oxygen concentration in the surface layer of the SiCN film subjected to the radical treatment was measured by X-ray Photoelectron Spectroscopy (XPS).

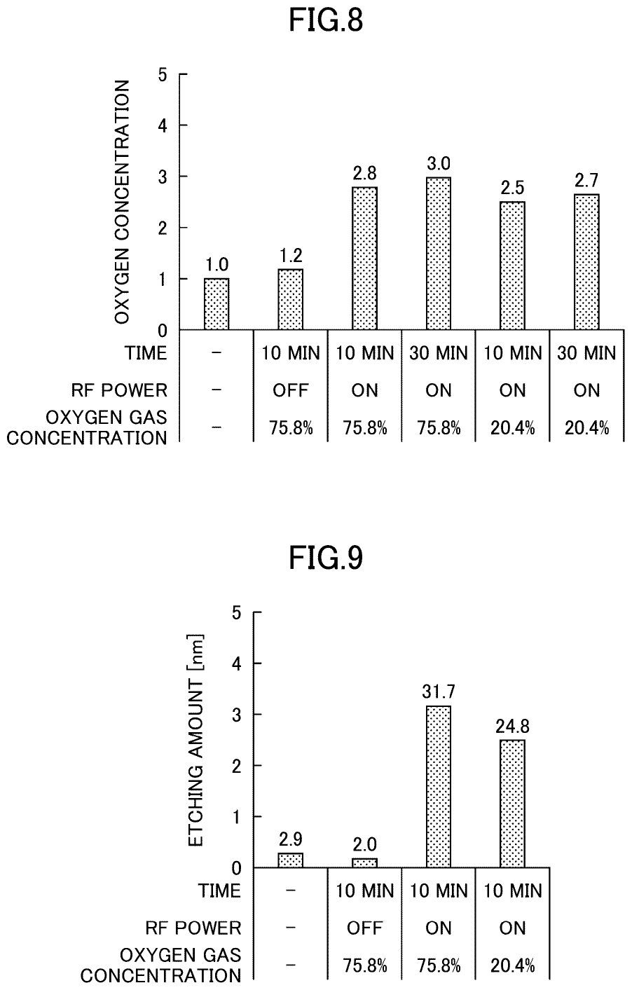

FIG. 8 shows the oxygen concentration in the surface layers of SiCN films. The leftmost bar graph in FIG. 8 shows the oxygen concentration in the surface layer of an SiCN film that was not subjected to the radical treatment. The second bar graph from the left shows the oxygen concentration in the surface layer of an SiCN film that was subjected to a treatment without radicals for 10 minutes with the RF power OFF at an oxygen gas concentration of 75.8% in the first processing gas. The third bar graph from the left shows the oxygen concentration in the surface layer of an SiCN film that was subjected to the radical treatment for 10 minutes with the RF power ON at the concentration of the oxygen gas of 75.8% in the first processing gas. The fourth bar graph from the left shows the oxygen concentration in the surface layer of an SiCN film that was subjected to the radical treatment for 30 minutes with the RF power ON at a concentration of the oxygen gas of 75.8% in the first processing gas. The fifth bar graph from the left shows the oxygen concentration in the surface layer of an SiCN film that was subjected to the radical treatment for 10 minutes with the RF power ON at a concentration of the oxygen gas of 20.4% in the first processing gas. The sixth bar graph from the left shows the oxygen concentration in the surface layer of an SiCN film that was subjected to the radical treatment for 30 minutes with the RF power ON at a concentration of the oxygen gas of 20.4% in the first processing gas. FIG. 8 shows the oxygen concentrations in the surface layers of the SiCN films that were subjected to the treatment without radicals and the radical treatment as relative values by regarding the oxygen concentration in the surface layer of the SiCN film that was not subjected to the radical treatment as being 1.

As shown in FIG. 8, the oxygen concentrations in the surface layers of the SiCN films subjected to the radical treatment were higher than the oxygen concentration in the surface layer of the SiCN film subjected to the treatment without radicals. This result suggests that the radical treatment had a greater effect of oxidizing the surface layer of an SiCN film than that of the treatment without radicals.

As shown in FIG. 8, the oxygen concentrations in the SiCN films in the case where the radical treatment time was 30 minutes were higher the oxygen concentrations in the SiCN films in the case where the radical treatment time was 10 minutes. From this result, it is considered possible to enhance the effect of oxidizing the surface layer of an SiCN film, by lengthening the radical treatment time.

As shown in FIG. 8, the oxygen concentrations in the surface layers of the SiCN films in the case where the oxygen concentration in the first processing gas in the radical treatment was 75.8% were higher than the oxygen concentrations in the surface layers of the SiCN films in the case where the oxygen concentration in the first processing gas in the radical treatment was 20.4%. From this result, it is considered possible to enhance the effect of oxidizing the surface layer of an SiCN film, by increasing the oxygen concentration in the first processing gas in the radical treatment.

### (Fourth Experiment)

First, substrates having SiCN films on surfaces thereof were prepared. Next, the prepared substrates were accommodated in the processing chamber 1 of the substrate processing apparatus 100, and subjected to steps S2 to S9 of the substrate processing method described above in the processing chamber 1. In step S6, the first number of times was set to 3. In step S2, the radical treatment time, the RF power, and the concentration of the oxygen gas contained in the first processing gas were changed. The conditions of the radical treatment (step S2) were as follows. The conditions of the COR treatment (step S4) and the thermal treatment (step S8) were the same as those of the COR treatment and the thermal treatment in the first experiment.

### (Radical Treatment)

Substrate temperature: 65° C.
Time: 10 minutes
RF power: OFF, ON
Concentration of the oxygen gas contained in the first processing gas: 75.8%, 20.4%

Next, the etching amounts of the SiCNs film were measured. FIG. 9 shows the etching amounts of the SiCN films. The leftmost bar graph in FIG. 9 shows the etching amount [nm] of an SiCN film that was not subjected to the radical treatment. The second bar graph from the left shows the etching amount [nm] of an SiCN film that was subjected to a treatment without radical for 10 minutes with the RF power OFF at a concentration of the oxygen gas of 75.8% in the first processing gas. The third bar graph from the left shows the etching amount [nm] of an SiCN film that was subjected to the radical treatment for 10 minutes with the RF power ON at a concentration of the oxygen gas of 75.8% in the first processing gas. The fourth bar graph from the left shows the etching amount [nm] of an SiCN film that was subjected to the radical treatment for 10 minutes with the RF power ON at a concentration of the oxygen gas of 20.4% in the first processing gas.

As shown in FIG. 9, the etching amounts of the SiCN films subjected to the radical treatment were greater than the etching amounts of the SiCN film that was not subjected to the radical treatment and of the SiCN film that was subjected to the treatment without radicals. This result indicates that performing the radical treatment before the COR treatment resulted in increasing the etching amounts of SiCN films.

As shown in FIG. 9, the etching amount of the SiCN film in the case where the oxygen concentration in the first processing gas in the radical treatment was 75.8% was greater than the etching amount of the SiCN film in the case where the oxygen concentration in the first processing gas in the radical treatment was 20.4%. This result indicates that increasing the concentration of the oxygen gas contained in the first processing gas in the radical treatment resulted in increasing the etching amount of the SiCN film.

From the results of the third and fourth experiments, it is considered that increasing the oxygen concentration in the oxide layer formed on the surface layer of the SiCN film before the COR treatment is effective in increasing the etching amount of the SiCN film.

The disclosed embodiments should be considered exemplary and non-limiting in all respects. Various omissions, substitutions, and modifications are applicable to the above embodiments without departing from the scope and spirit of the appended claims.

In the above embodiments, a case where the substrate processing apparatus is a batch-type apparatus for processing a plurality of substrates at a time has been described. However, the present disclosure is not limited to this. For example, the substrate processing apparatus may be a single wafer-type apparatus for processing one substrate at a time.

According to the present disclosure, it is possible to control the etching amount of a nitride film.

What is claimed is:

1. A substrate processing method, comprising:
(a) preparing a substrate having a nitride film on a surface thereof;
(b) exposing the substrate to a plasma generated from a first processing gas containing hydrogen gas and oxygen gas;
(c) supplying a second processing gas containing a fluorine-containing gas and a basic gas to the substrate;
(d) performing the (b) and the (c) in this order a first number of times; and
(e) thermally treating the substrate after the (d).

2. The substrate processing method according to claim 1,
wherein the (b) includes forming an oxide layer by oxidizing a surface layer of the nitride film.

3. The substrate processing method according to claim 2,
wherein the (c) includes denaturing the oxide layer into a reaction product, and
the (e) includes sublimating and removing the reaction product.

4. The substrate processing method according to claim 1,
wherein the (b) includes maintaining a temperature of the substrate at a first temperature,
the (c) includes maintaining the temperature of the substrate at a second temperature, and
the second temperature is the same as the first temperature.

5. The substrate processing method according to claim 4,
wherein the (e) includes maintaining the temperature of the substrate at a third temperature, and
the third temperature is higher than the second temperature.

6. The substrate processing method according to claim 1,
wherein the (c) is performed in a same processing chamber as that in which the (b) is performed.

7. The substrate processing method according to claim 1,
wherein the nitride film is an SiN film, an SiCN film, or a BN film.

8. A substrate processing apparatus, comprising:
a processing chamber;
a gas supply part configured to supply a processing gas into the processing chamber; and
a controller,
wherein the controller is configured to perform:
(a) preparing a substrate having a nitride film on a surface thereof;
(b) exposing the substrate to a plasma generated from a first processing gas containing hydrogen gas and oxygen gas;
(c) supplying a second processing gas containing a fluorine-containing gas and a basic gas to the substrate;
(d) performing the (b) and the (c) in this order a first number of times; and
(e) thermally treating the substrate after the (d).
